(19) United States
(12) Patent Application Publication
(10) Pub. No.: US 2008/0303066 A1
(43) Pub. Date: Dec. 11, 2008

(54) SEMICONDUCTOR DEVICE

(75) Inventors: Yasuaki Yonemochi, Tokyo (JP); Hisakazu Otoi, Tokyo (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 12/118,731

(22) Filed: May 11, 2008

(30) Foreign Application Priority Data
Jun. 8, 2007 (JP) 2007-152752

(51) Int. Cl. H01L 23/538

(52) U.S. Cl. 257/208; 257/E23.173

(57) ABSTRACT

A semiconductor device is provided which can suppress the deterioration of its reliability caused by liquid soaking into a gap. The semiconductor device includes plural gate electrode layers and an interlayer insulating film. The gate electrode layers are formed so as to extend in the same direction in a planar layout and each have a gate wiring portion and a contact pad portion. The interlayer insulating film is formed over the gate electrode layers and gaps so as to leave the gaps each between adjacent gate wiring portions and also between adjacent gate wiring portion and contact pad portion. A second spacing which is the distance between adjacent gate wiring portion and contact pad portion is 2.1 times or less as large as a first spacing which is the distance between adjacent gate wiring portions.

### CROSS-REFERENCE TO RELATED APPLICATIONS

The disclosure of Japanese Patent Application No. 2007-152752 filed on Jun. 8, 2007 including the specification, drawings and abstract is incorporated herein by reference in its entirety.

### BACKGROUND OF THE INVENTION

The present invention relates to a semiconductor device and more particularly to a semiconductor device having a gap portion between gates.

Reduction of size and microfabrication of semiconductor memories have been being performed, and as to the layout of transistor gate wiring within a memory array, a layout based on a minimum design rule (L/S (Line and Space) rule is adopted in many cases. At an end of the wiring layout thus based on the minimum L/S rule there is provided a contact pattern (contact pad portion) for electric connection with the wiring (see, for example, Patent Literature 1).

As a semiconductor memory having gate wiring there is known, for example, a flash memory of AG-AND (Assist Gate-AND) type, which has on a main surface side of a semiconductor substrate a plurality of assist gates for forming an inversion layer, a floating gate formed between the assist gates, and a control gate formed on the floating gate, (see, for example, Patent Literature 2).

According to Patent Literature 2, a method for manufacturing the AG-AND type flash memory comprises the steps of forming assist gates on a main surface of a semiconductor substrate, forming an insulating film so as to cover the assist gates, dry-etching the insulating film to form side walls on both side faces of each of the assist gates, expose the main surface of the semiconductor substrate positioned between the side walls, allowing an insulating film to grow on the main surface portion of the semiconductor substrate positioned between the side walls to form a tunnel insulating film of a floating gate, and filling a conductive layer into the concave portion between the side walls to form a floating gate.

In the construction of the flash memory described above, an insulating film is filled between floating gates. Therefore, with the progress of microfabrication, the spacing between floating gates becomes narrower and the capacity between floating gates increases. Thus, there has been the problem that when the amount of electric charge accumulated within the floating gate of a selected memory cell varies in reading operation, there occurs a so-called threshold voltage Vth blur which is a variation in threshold voltage of the selected memory cell, with consequent easy occurrence of malfunction.

On the other hand, there has been proposed a technique in which an insulating material is not buried completely between wiring lines, but a cavity (gap) having a closed upper portion is formed between wiring lines to reduce the wiring capacitance (see, for example, Patent Literature 3).

In Patent Literature 3 there is described a construction having plural wiring lines formed on a substrate so as to be equally spaced from one another and also having an insulating film formed so as to leave a gap between adjacent such wiring lines. According to this construction, since the size between adjacent wiring lines is the same, the size of the cavity formed between wiring lines is simplified and hence the wiring capacitance can be set to a desired value.

[Patent Literatures]

1. Japanese Patent Laid-Open No. 2004-15056

2. Japanese Patent Laid-Open No. 2005-85903

3. Japanese Patent Laid-Open No. Hei 11 (1999)-67899

### SUMMARY OF THE INVENTION

According to the technique disclosed in Patent Literature 3, since the spacing between adjacent wiring lines is the same, the size of the cavity (gap) formed between adjacent wiring lines is simplified. In this patent literature, however, no consideration is given to the cavity between the wiring portion and the contact pad portion. Consequently, there occur variations between the closure shape above the cavity formed between adjacent wiring lines and that above the cavity formed between the wiring portion and the contact pad portion.

Once there occur such variations in the closure shape above the cavities, there occur variations also in the moisture resistance of the closed portions. Liquid is apt to penetrate a cavity poor in moisture resistance through the associated closed portion. In this case, liquid such as washing is apt to remain after a wet process such as a washing process. Thus, there has been the problem that there occurs corrosion of wiring, with consequent deterioration in reliability of the semiconductor device concerned.

The present invention has been accomplished in view of the above-mentioned problem and it is an object of the invention to provide a semiconductor device capable of suppressing the deterioration in reliability of the device caused by liquid soaking into a cavity.

A semiconductor device embodying the present invention is comprised of a semiconductor substrate having a main surface, a plurality of gate electrode layers formed over the semiconductor substrate, and an interlayer insulating film. The gate electrode layers are formed so as to extend in the same direction in a planar layout and are each provided with a gate wiring portion and a contact pad portion. The interlayer insulating film is formed over the gate electrode layers and gaps so as to leave the gaps each between adjacent gate wiring portions and also between adjacent gate wiring portion and contact pad portion. A second spacing which is the distance between adjacent gate wiring portion and contact pad portion is 2.1 times or less as large as a first spacing which is the distance between adjacent gate wiring portions.

According to the semiconductor device of this embodiment, the second spacing, i.e., the distance between adjacent gate wiring portion and contact pad portion, is 2.1 times or less as large as the first spacing, i.e., the distance between adjacent gate wiring portions. Consequently, it is possible to diminish the difference in closure shape between the gap formed between adjacent gate wiring portions and the gap formed between adjacent gate wiring portion and contact pad portion. As a result, it is possible to diminish variations in moisture resistance of the gaps and there no longer occurs penetration of liquid into a specific gap of a low moisture resistance in the wet process. Thus, it is possible to prevent the deterioration in reliability of the semiconductor device caused for example by the corrosion of wiring.

### BRIEF DESCRIPTION OF THE DRAWINGS

FIG. 1 is a plan view showing schematically the construction of a semiconductor device according to a first embodiment of the present invention;

FIG. 2 is a schematic sectional view taken on line II-II in FIG. 1;

FIG. 3 is a schematic sectional view showing taken along line III-III in FIG. 1;

FIG. 4 is a schematic sectional view showing a first step in a method of manufacturing the semiconductor device according to the first embodiment;

FIG. 5 is a schematic sectional view showing the first step in the method of manufacturing the semiconductor device according to the first embodiment;

FIG. 6 is a schematic sectional view showing a second step in the method of manufacturing the semiconductor device according to the first embodiment;

FIG. 7 is a schematic sectional view showing the second step in the method of manufacturing the semiconductor device according to the first embodiment;

FIG. 8 is a schematic sectional view showing a third step in the method of manufacturing the semiconductor device according to the first embodiment;

FIG. 9 is a schematic sectional view showing the third step in the method of manufacturing the semiconductor device according to the first embodiment;

FIG. 10 is a plan view showing schematically a comparative construction in comparison with the semiconductor device of the first embodiment;

FIG. 11 is a schematic sectional view taken along line XI-XI in FIG. 10;

FIG. 12 is a plan view showing schematically a planar layout of gate electrode layers in a third embodiment of the present invention;

FIG. 13 is a schematic explanatory diagram showing a planar layout of gate electrode layers in a semiconductor device according to a fourth embodiment of the present invention;

FIG. 14 is a schematic explanatory diagram showing a planar layout of gate electrode layers as a comparative example in comparison with the semiconductor device of the fourth embodiment;

FIG. 15 is a schematic explanatory diagram showing a planar layout of gate electrode layers in a semiconductor device according to a fifth embodiment of the present invention;

FIG. 16 is a schematic explanatory diagram showing a planar layout of gate electrode layers in a semiconductor device according to a first modification of the fifth embodiment;

FIG. 17 is a schematic explanatory diagram showing a planar layout of gate electrode layers in a semiconductor device according to a second modification of the fifth embodiment;

FIG. 18 is a schematic explanatory diagram showing a planar layout of gate electrode layers and dummy conductive layers in a semiconductor device according to a sixth embodiment of the present invention;

FIG. 19 is a schematic explanatory diagram showing a planar layout of gate electrode layers and dummy conductive layers in a semiconductor device according to a modification of the sixth embodiment;

FIG. 20 is a schematic explanatory diagram showing a planar layout of gate electrode layers and an outer periphery conductive layer in a semiconductor device according to a seventh embodiment of the present invention;

FIG. 21 is a schematic explanatory diagram showing a planar layout of gate electrode layers and an outer periphery conductive layer in a semiconductor device according to a first modification of the seventh embodiment;

FIG. 22 is a schematic explanatory diagram showing a planar layout of gate electrode layers and an outer periphery conductive layer in a semiconductor device according to a second modification of the seventh embodiment;

FIG. 23 is a schematic explanatory diagram showing a planar layout of gate electrode layers and an outer periphery conductive layer in a semiconductor device according to a third modification of the seventh embodiment;

FIG. 24 is a schematic explanatory diagram showing a planar layout of gate electrode layers and an outer periphery conductive layer in a semiconductor device according to a fourth modification of the seventh embodiment;

FIG. 25 is a schematic explanatory diagram showing a planar layout of gate electrode layers and an outer periphery conductive layer in a semiconductor device according to a fifth modification of the seventh embodiment;

FIG. 26 is a schematic explanatory diagram showing a planar layout of gate electrode layers, dummy conductive layers and an outer periphery conductive layer in a semiconductor device according to an eighth embodiment of the present invention;

FIG. 27 is a schematic explanatory diagram showing a planar layout of gate electrode layers, dummy conductive layers and an outer periphery conductive layer in a semiconductor device according to a modification of the eighth embodiment;

FIG. 28 is a diagram showing a schematic circuit configuration of NAND type;

FIG. 29 is a plan view showing schematically the construction of a semiconductor device according to a ninth embodiment of the present invention;

FIG. 30 is a schematic sectional view taken along line XXX-XXX in FIG. 29;

FIG. 31 is a schematic sectional view taken along line XXXI-XXXI in FIG. 29; and

FIG. 32 is a graph showing schematically the relation between a spacing size ratio and lower-limit values of a contact hole aspect ratio.

### DETAILED DESCRIPTION OF PREFERRED EMBODIMENTS

Embodiments of the present invention will be described below with reference to the accompanying drawings.

### First Embodiment

In this first embodiment reference will be made to a flash memory of AG-AND type as an example.

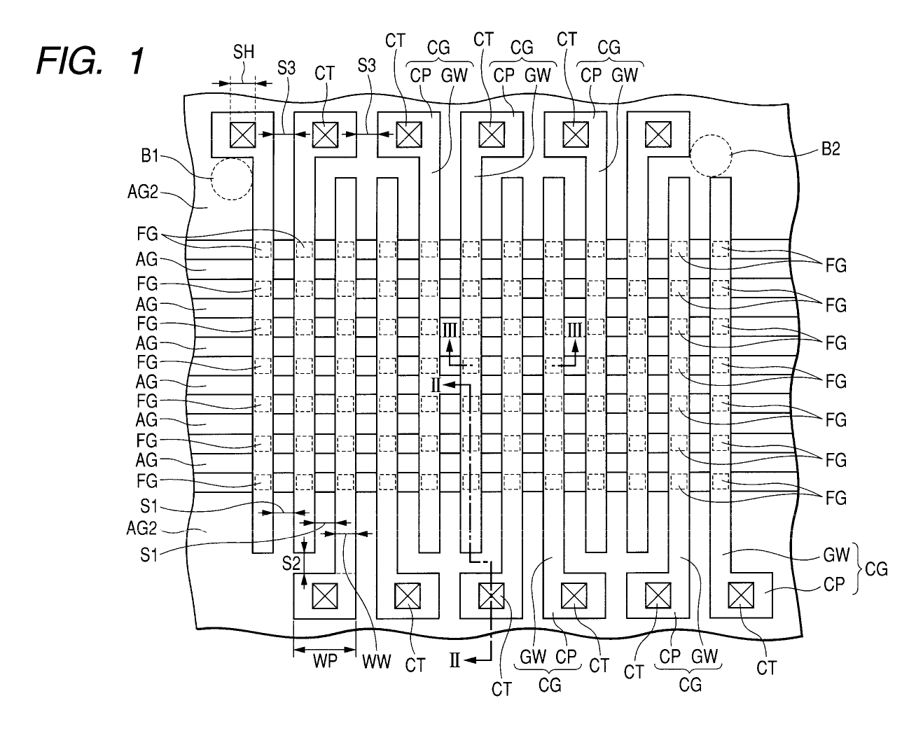

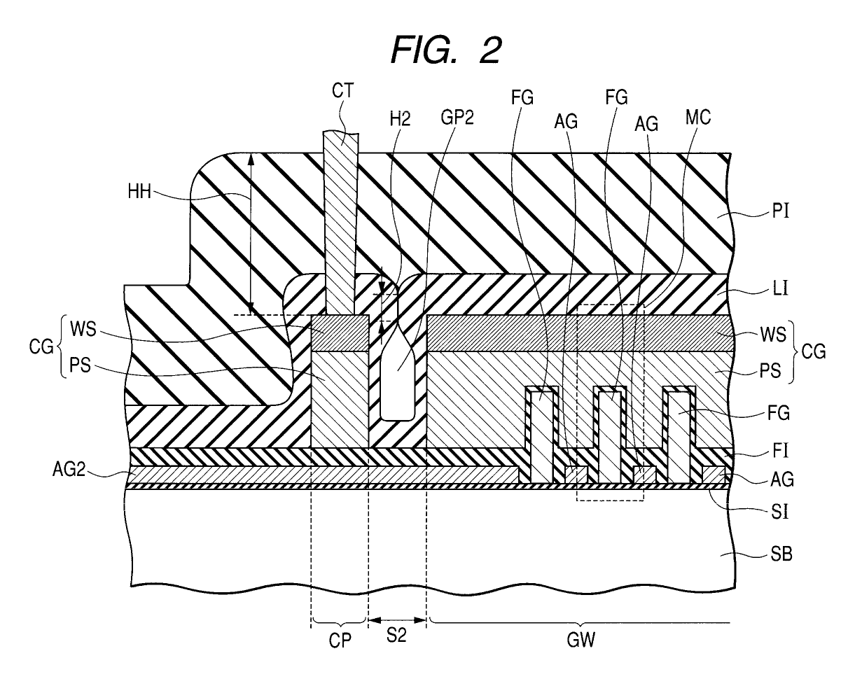

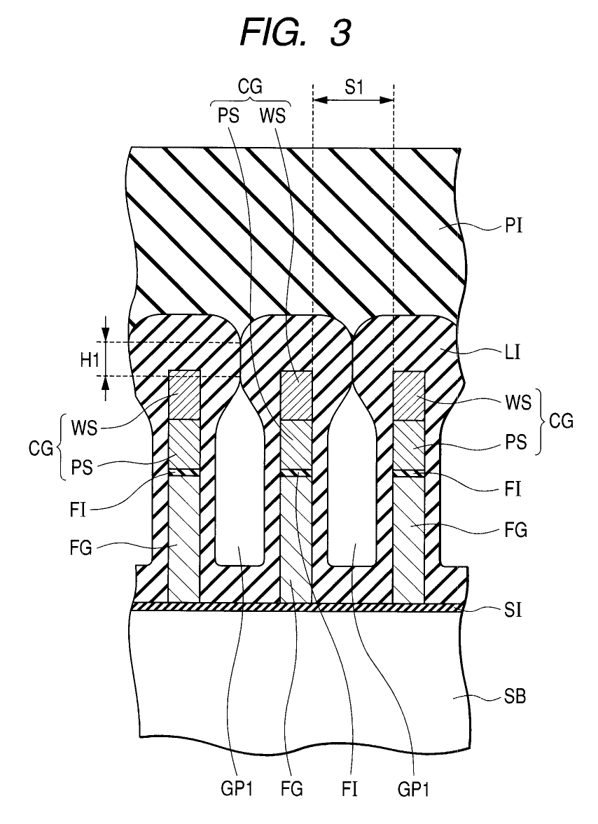

FIG. 1 is a plan view showing schematically the construction of a semiconductor device according to a first embodiment of the present invention. FIGS. 2 and 3 are schematic sectional views taken along lines II-II and III-III, respectively, in FIG. 1.

Referring mainly to FIG. 1, on a main surface of a semiconductor substrate SB formed of silicon for example, there are formed plural control gates (gate electrode layers) CG so as to extend side by side in the same direction (vertical direction in the figure) in a planar layout, and plural assist gates AG are formed side by side so as to perpendicularly intersect the control gates CG. Floating gates (floating gate electrode layers) FG are formed below the control gates CG each in an area sandwiched in between adjacent assist gates AG.

In a planar layout, each control gate CG has a gate wiring portion GW and a contact pad portion CP. The control gate CG is a portion constituting a principal portion of the control gate CG and having a dimension WW in the width direction (lateral direction in the figure). The contact pad portion CP is a portion positioned at one end of the control gate CG and having a dimension WP larger than the dimension WW in the width direction (lateral direction in the figure). A contact CT having a width dimension SH is formed on the contact pad portion CP. A boundary between the gate wiring portion GW and the contact pad portion CP is, for example, a broken-line portion in FIG. 1.

Adjacent gate wiring portions GW are spaced from each other by a distance of a spacing dimension S1 in a planar layout. Usually, the spacing dimension S1 is a minimum wiring spacing in the semiconductor device. Adjacent gate wiring portion GW and contact pad portion CP are spaced from each other by a distance of a spacing dimension S2. The control gates CG are formed in such a manner that the spacing dimension S2 is 2.1 times or less as large as the spacing dimension S1. Since the spacing dimension S1 usually corresponds to the minimum wiring spacing in the semiconductor device, the spacing dimension S2 is larger than the spacing dimension S1.

Adjacent contact pad portions CP are spaced from each other by a distance of a spacing dimension S3. The control gates CG are formed in such a manner that the spacing dimension S3 is 2.1 times or less as large as the spacing dimension S1. Since the spacing dimension S1 usually corresponds to the minimum wiring spacing in the semiconductor device, the spacing dimension S3 is larger than the spacing dimension S1.

Referring mainly to FIG. 2, plural memory cells are formed on the semiconductor substrate SB. Each of the memory cells has as principal components a pair of assist gates AG, a floating gate FG and a control gate CG. One memory cell is formed within an area MC enclosed with a broken line in the figure.

The pair of assist gates AG are each formed on the surface of the semiconductor substrate SB through an insulating film SI. The floating gate FG is formed over the surface of the semiconductor substrate SB through the insulating film SI so as to sandwich in between the pair of assist gates AG. The control gate CG is formed on the floating gate FG so as to confront the floating gate FG through an insulating film F1. The insulating film F1 is formed also on an upper surface and side faces of each assist gate AG.

The assist gates AG and the floating gate FG are each formed of a polycrystalline silicon (an impurity-doped polycrystalline silicon of a low resistance) for example. The control gate CG is formed by a laminate film of both a conductor film PS formed of a polycrystalline silicon of a low resistance for example and a high melting metal silicide film WS such as a tungsten silicide (WSiₓ) film formed on the conductor film PS. The insulating film SI is formed a silicon oxide film (SiO₂) for example.

An interlayer insulating film LI and an insulating film PI are formed on an upper surface of the control gate CG.

The contact CT extends through both interlayer insulating film LI and insulating film PI at a depth HH. Through the contact CT the control gate CG is electrically coupled to wiring provided on top of the insulating film PI. An assist gate AG2 positioned below an end of the gate wiring portion GW also underlies the portion beyond the terminal end of the gate wiring portion GW and a contact pad portion CP is formed thereon through the insulating film F1.

As noted above, the gate wiring portion GW and the contact pad portion CP are spaced from each other by the spacing dimension S2. Consequently, a concave pattern is formed between the gate wiring portion GW and the contact pad portion CP. The interlayer insulating film LI is formed so as to cover inner side faces, upper surfaces of side potions and bottom of that concave pattern. The portions of the interlaying insulating film LI which cover inner side faces of the concave pattern project inwards at the upper portion of the concave pattern and the projecting portions contact each other over a range of height dimension H2 at a position above the central part of the concave pattern. As a result, a gap GP2 closed with the interlayer insulating film LI is formed within the concave pattern.

Thus, the gap GP2 is formed in the portion of the spacing dimension S2 between the gate wiring portion GW and the contact pad portion CP and it has a closed portion over the range of the height dimension H2 at an upper position thereof.

The insulating film PI is formed on the interlayer insulating film LI. Referring mainly to FIG. 3, in the illustrated section, there are formed plural convex patterns each being a laminate of both floating gate FG and control gate CG. In a planar layout, the convex patterns each correspond to the gate wiring portion GW, so that the spacing between adjacent such convex patterns corresponds to the spacing dimension S1 which is a spacing dimension between adjacent wiring portions GW as noted above.

The interlayer insulating film LI is formed so as to cover side faces and an upper surface of each of the convex patterns and also cover the bottom between the convex portions. The portions of the interlayer insulating film LI which cover side faces of the convex patterns project sideways at the upper portions of the convex patterns and are in contact with each other over a range of a height dimension H1 at the portion between the convex patterns. In this way gaps GP1 closed with the interlayer insulating film LI are formed each between adjacent convex patterns.

That is, each gap GP1 is formed in the portion of a spacing dimension S1 between adjacent gate wiring portions GW. The gap GP1 has a closed portion over a range of the height dimension H1 at a position thereabove.

The gaps GP1 and GP2 are each formed in the position of the pattern gap portion between adjacent control gates CG, but since the spacing dimension S2 is 2.1 times or less as large as the spacing dimension S1, a dimensional difference between the gaps is suppressed to a difference of not larger than 2.1 times between the gaps GP1 and GP2. As a result, the difference in shape between the gaps GP1 and GP2 is diminished and therefore the difference between the height dimension H1 of the closed portion of each gap GP1 and the height dimension H2 of the closed portion of each gap GP2 is also diminished.

Next, a description will be given about the details of the planar layout of the control gates CG. Referring to FIG. 1, out of both end portions in the length direction (vertical direction in the figure) of each gate wiring portions GW, the side where the contact pad CP is formed alternates every two control gates in the layout of the control gates CG.

In each control gate CG and in the connection (broken-line portion in the figure) between the contact pad portion CP and the gate wiring portion GW, one outer edges running in the extending direction of the control gate CG are linked in a rectilinear shape. The other outer edge of the contact pad portion CP running in the extending direction of the control gate CG projects with respect to the gate wiring portion GW.

Further, adjacent contact pad portions CP formed on the same side in the extending direction of the control gate CG project as above in directions away from each other.

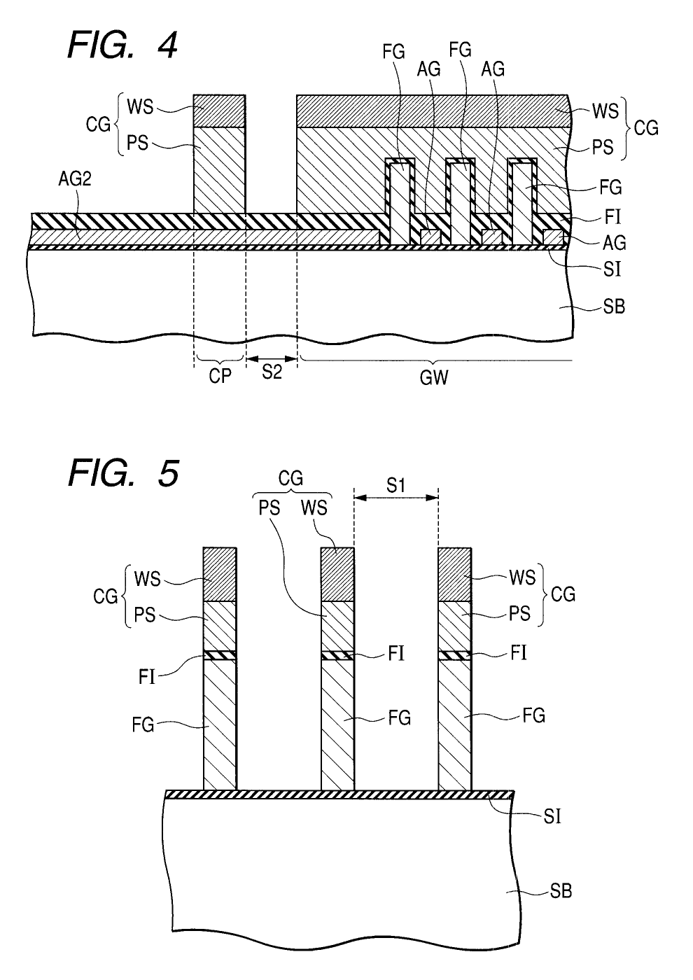

A method of manufacturing the semiconductor device of this first embodiment will now be described with reference to FIGS. 4 to 9. FIGS. 4 and 5 are schematic sectional views showing a first step in the semiconductor device manufacturing method according to the first embodiment. Sectional positions of FIGS. 4 and 5 correspond to the positions of lines II-II and III-III, respectively, in FIG. 1.

Referring to FIGS. 4 and 5, floating gates FG in a memory array are subjected to etching with control gates CG as masks in a conventional manufacturing flow, whereby laminate gates (convex patterns) of memory cells are formed on the surface of the semiconductor substrate SB.

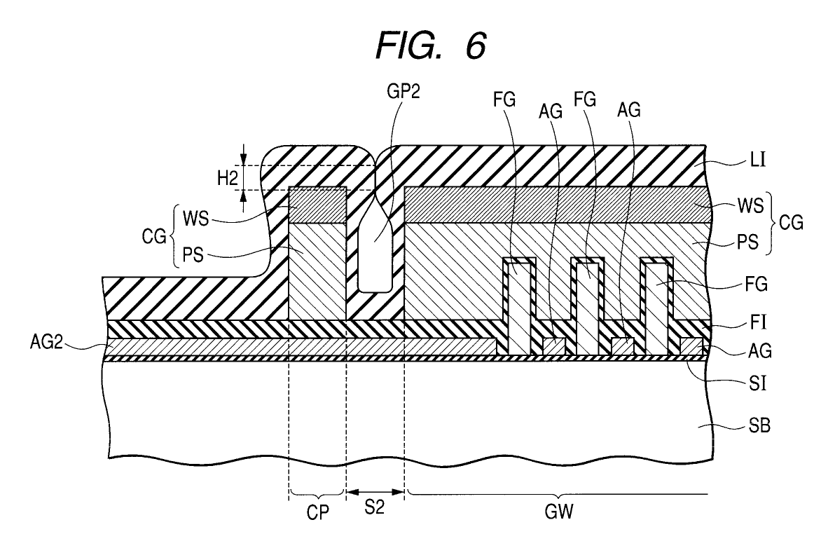

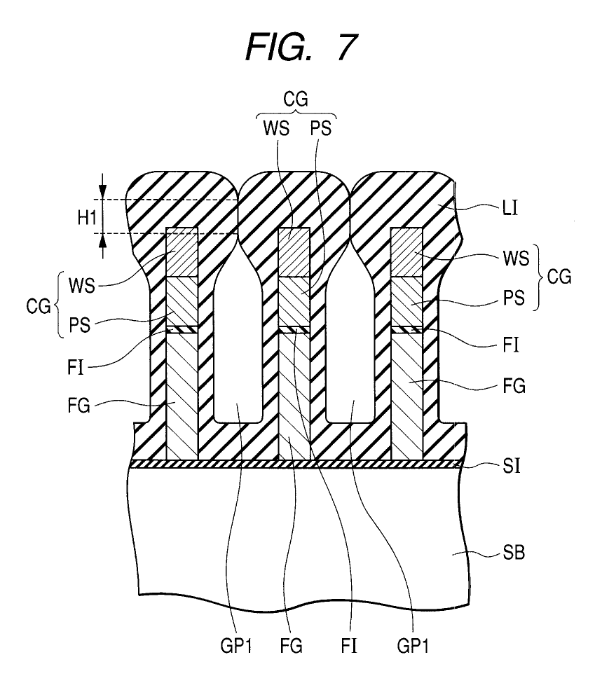

FIGS. 6 and 7 are schematic sectional views showing a second step in the semiconductor device manufacturing method according to the first embodiment. Sectional positions of FIGS. 6 and 7 correspond to positions of lines II-II and III-III, respectively in FIG. 1.

Referring to FIGS. 6 and 7, in order to form gaps GP1 and GP2 which are closed at upper positions thereof, an interlayer insulating film L1 is formed by a film forming method poor in step coverage.

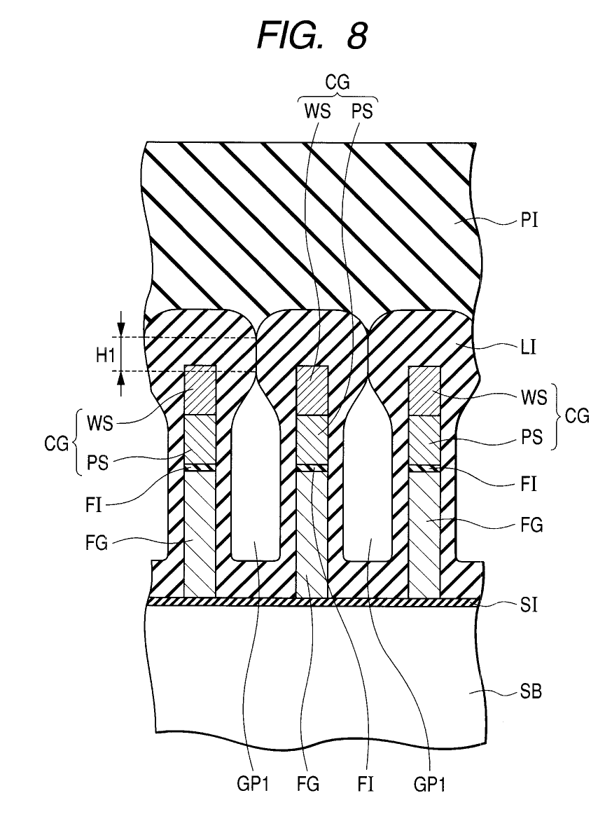

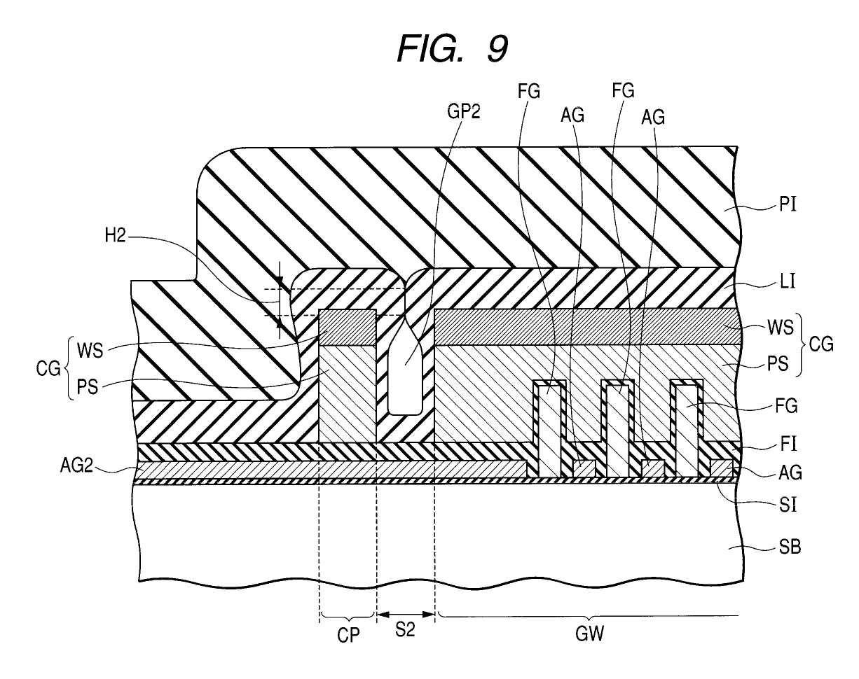

FIGS. 8 and 9 are schematic sectional views showing a third step in the semiconductor device manufacturing method according to the first embodiment. Sectional positions of FIGS. 8 and 9 correspond to positions of lines II-II and III-III, respectively, in FIG. 1.

Referring to FIGS. 8 and 9, an insulating film PI is formed on the interlayer insulating film L1. Referring to FIGS. 1 to 3, contact holes are formed so as to reach the control gates CG through the interlayer insulating film L1 and the insulating film PI with use of the conventional photomechanical process and etching technique. The contact holes are each formed at a width dimension of SH (FIG. 1) and a depth dimension of HH (FIG. 2). The width dimension SH is larger than the spacing dimension S1 and is in many cases formed in accordance with a design rule of about twice that of the spacing dimension S1. The depth dimension HH is set large enough to prevent the soaking of liquid into the gaps GP1 and GP2 in subsequent steps. Then, contacts CT are formed so as to fill up the contact holes. In this way there is fabricated the semiconductor device of this embodiment. As to the steps which follow, explanations thereof will here be omitted because they are the same as in the conventional process related to a stacked wiring structure.

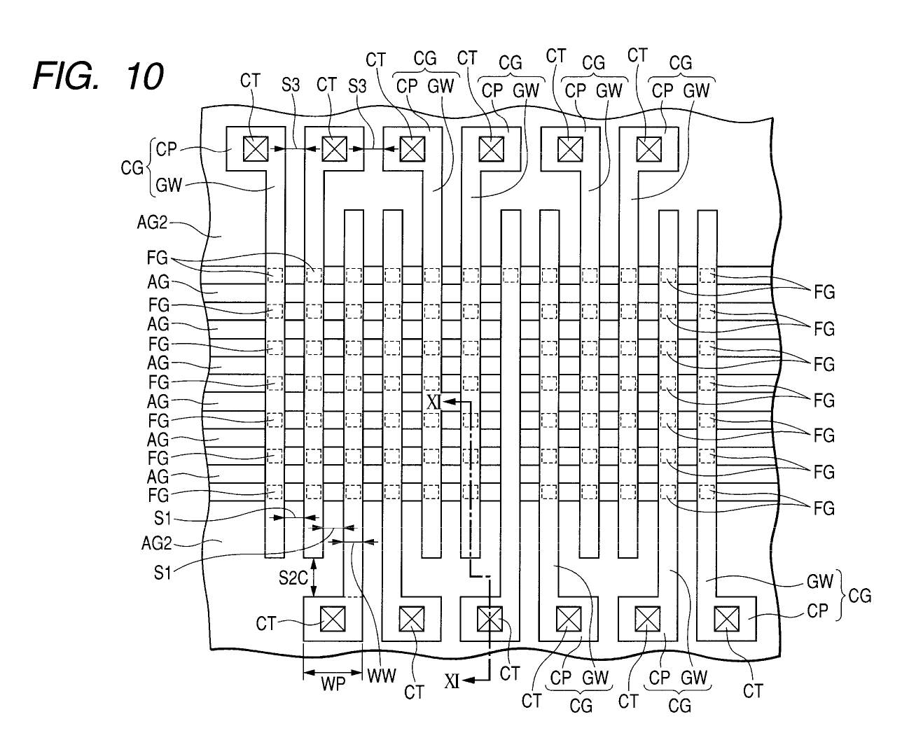

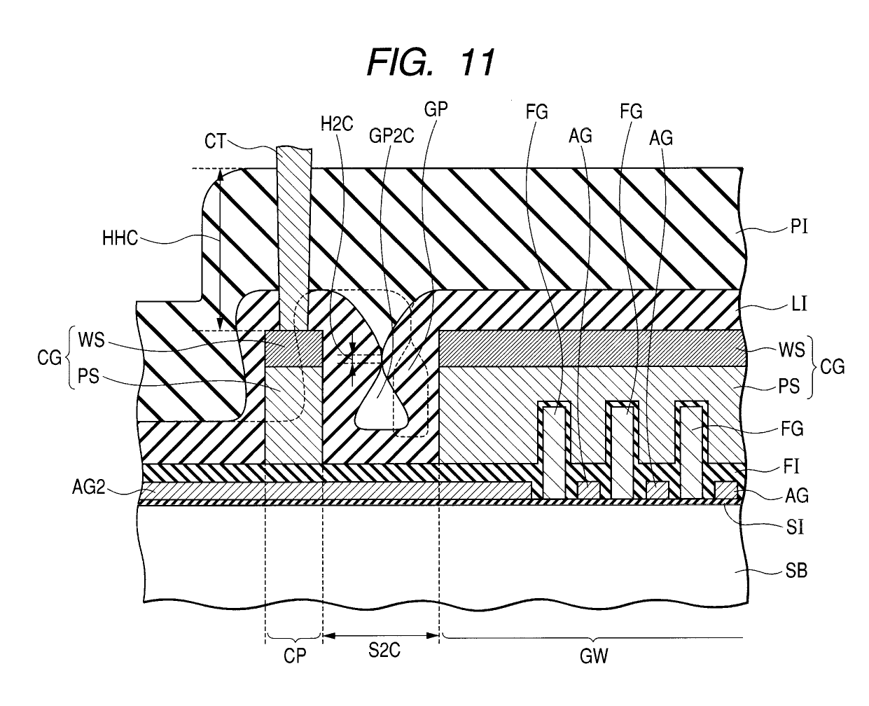

FIG. 10 is a plan view showing schematically a comparative construction in comparison with the semiconductor device of the first embodiment and FIG. 11 is a schematic sectional view taken along line XI-XI in FIG. 10.

Referring to FIG. 10, in a planar layout, the distance between a gate wiring portion GW and a contact pad portion CP corresponds to a spacing dimension S2C. The spacing dimension S2C is set at a distance larger than 2.1 times the spacing dimension S1 of the distance between adjacent gate wiring portions GW.

Referring mainly to FIG. 11, as a result of the distance between the gate wiring portion GW and the contact pad portion CP being larger than 2.1 times the distance between adjacent gate wiring portions GW, a gap portion GP2C in the illustrated comparative example is smaller in height dimension of a gap closed portion than that of the gap GP2 (a broken-line portion in the figure) in the first embodiment. That is, a height dimension H2C of the closed portion of the gap GP2C is smaller than the height dimension H2 of the closed portion of the gap GP2. Therefore, in order to prevent soaking of liquid in the gap GP2C in subsequent steps, the depth dimension HHC is set larger than the depth dimension HH (FIG. 2). The position of the closed portion of the gap GP2C is lower than that of the gap GP2.

According to this first embodiment, the spacing dimension S2 (FIG. 2) between a gate wiring portion GW and a contact pad portion CP is set 2.1 times or less as large as the spacing dimension S1 (FIG. 3) between adjacent gate wiring portions GW. As a result, the difference between the height dimension H2 of the closed portion of the gap GP2 (FIG. 2) and the height dimension H1 of the closed portion of the gap GP1 (FIG. 3) is diminished. Consequently, it is possible to diminish variations in moisture resistance of the gaps and prevent the penetration of liquid into the gaps.

To make sure the liquid penetration preventing action described above, the present inventors have made a study of a correlation between the ratio of the spacing dimension S2 to the spacing dimension S1, i.e., S2/S1, and lower-limit values of each contact hole aspect ratio with the contact hole CT (FIGS. 1 and 2) embedded therein.

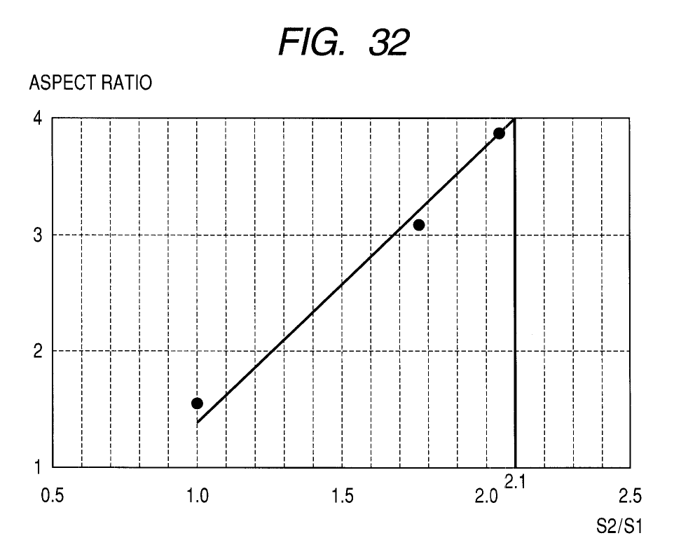

FIG. 32 is a graph showing schematically the relation between the ratio S2/S1 and lower-limit values of the contact hole aspect ratio. The aspect ratio is a value resulting from dividing the depth dimension HH (FIG. 2) by the width dimension SH (FIG. 1), the depth dimension HH being a depth at which the contact hole extend through both interlayer insulating film L1 and insulating film PI. The width dimension SH was set twice as large as the spacing dimension s1. Further, the spacing dimension S1 was set at 65 nm.

Reference to FIG. 32 shows that, with changes in the ratio S2/S1, the aspect ratio lowers as the ratio S2/S1 approaches 1 from its state larger than 1 and that the aspect ratio can be made 4 or less by setting the ratio S2/S1 at 2.1 or less. That is, it turned out that by setting the ratio S2/S1 at 2.1 or less, variations of the gaps were diminished and the penetration of liquid into the gaps was prevented even at small thicknesses of the interlayer insulating film LI and the insulating film PI.

In a step of forming fine contact holes about 130 nm in width dimension for example, a stable microfabrication can be effected by setting the aspect ratio at as small as 4 or less. By setting the ratio S2/S1 at 2.1 or less and the aspect ratio at 4 or less it is possible, in an industrial semiconductor device manufacture, to approach the moisture resistance of the gap portions GP2 to that of the gaps GP1 and prevent the penetration of liquid into a specific gap of a low moisture resistance in the wet process. Consequently, it is possible to prevent a lowering in reliability of the semiconductor device caused by the corrosion of wiring for example.

Each control gate CG is formed in such a manner that the spacing dimension S3 (FIG. 1) between adjacent contact pad portions CP is 2.1 times or less as large as the spacing dimension S1 referred to above. As a result, the difference between the height dimension of the closed portion of the gap formed between adjacent contact pad portions CP and the height dimension H1 referred to above is diminished. Consequently, in the wet process, it is possible to prevent easy penetration of particularly liquid into the gap between adjacent contact pad portions CP. Thus, it is possible to prevent the occurrence of corrosion of wiring caused by soaking liquid and hence possible to prevent a lowering in reliability of the semiconductor device. Besides, contact holes can be formed in a satisfactory yield industrially.

As shown in FIG. 1, each control gate CG is formed in such a manner that the width dimension WP (FIG. 1) of its contact pad portion CP is larger than the width dimension WW of its gate wiring portion GW. As a result, not only the gate wiring can be formed in accordance with a minimum design rule, but also the contact pad portion CP can be formed large. Consequently, a high integration degree of the semiconductor device is ensured and at the same time an electrical coupling with the control gate CG can be done in a positive manner.

### Second Embodiment

Referring to FIG. 1, in this second embodiment each control gate CG is formed in such a manner that the spacing dimensions S1 and S2 become equal to each other.

Further, each control gate CG is formed in such a manner that the spacing dimensions S1 and S3 become equal to each other.

Gaps GP1 and GP2 are each formed in the position of the pattern gap portion of each control gate CG, but since the spacing dimensions S1 and S2 are equal to each other, the dimension of the gap GP1 and that of the gap GP2 are equal to each other. As a result, the gaps GP1 and GP2 are closed in similar shapes, so that the height dimension H1 of the closed portion of the gap GP1 and the height dimension H2 of the closed portion of the gap GP2 are equal to each other.

According to this second embodiment, the spacing dimension S2 (FIG. 2) between the gate wiring portion GW and the contact pad portion CP and the spacing dimension S1 (FIG. 3) between adjacent gate wiring portions GW are made equal to each other. As a result, the interlayer insulating film L1 formed between the gate wiring portion GW and the contact pad portion CP and the interlayer insulating film LI formed between adjacent gate wiring portions GW close in the same manner. Consequently, the height dimension H2 of the closed portion of the gap GP2 (FIG. 2) and the height dimension H1 of the closed portion of the gap GP1 (FIG. 3) become equal to each other.

Since the height dimension H2 of the closed portion of the gap GP2 and the height dimension H1 of the closed portion of the gap GP1 are equal to each other, the gap GP2 can prevent liquid from penetrating the gap interior to about the same degree as the gap GP1 formed between adjacent gate wiring portions GW. In other words, the gap GP2 can have about the same degree of moisture resistance as the gap GP1. Accordingly, it is possible to prevent liquid from penetrating only the gap GP2 to induce the corrosion of wiring and hence possible to prevent a lowering in reliability of the semiconductor device.

Each control gate CG is formed in such a manner that the spacing dimension S3 (FIG. 1) between adjacent contact pad portions CP is equal to the spacing dimensions S1 and S2 referred to above. As a result, the height dimension of the closed portion of the gap formed between adjacent control gates CG also becomes equal to the height dimensions H1 and H2 referred to above. Thus, in the wet process, it is possible to prevent easy penetration of particularly liquid into the gap between adjacent contact pad portions CP. Accordingly, it is possible to prevent the occurrence of wiring corrosion caused by soaking liquid and hence possible to prevent a lowering in reliability of the semiconductor device.

Further, as shown in FIG. 1, each control gate CG is formed in such a manner that the width dimension WP (FIG. 1) of the contact pad portion CP is larger than the width dimension WW of the gate wiring portion GW. As a result, not only the gate wring is formed in accordance with a minimum design rule, but also the contact pad portion CP can be formed large. Consequently, a high integration degree of the semiconductor device is attained and at the same time an electric coupling with the control gate CG can be done in a positive manner.

### Third Embodiment

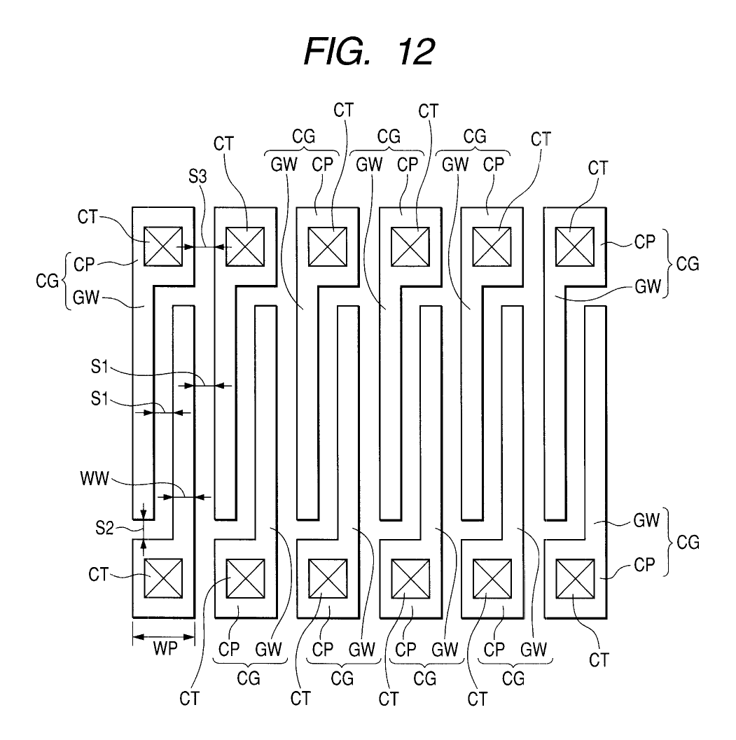

FIG. 12 is a plan view showing schematically a planar layout of gate electrode layers (control gates) in a third embodiment of the present invention.

A planar layout of control gates CG in this third embodiment corresponds to a pattern of a shape obtained by removing band-like patterns of width dimensions S1, S2 and S3 from a minimum rectangular pattern including all of plural control gates CG.

The control gates CG are formed in such a manner that adjacent contact pad portions CP project in the same direction with respect to the gate wiring portions GW.

Other constructional points of this third embodiment are almost the same as in the construction of the previous first or second embodiment. Therefore, the same elements as in the previous first or second embodiment are identified by the same reference numerals as in the previous embodiment and explanations thereof will here be omitted.

Next, a description will be given about the difference in point of effect between this third embodiment and the first embodiment. As shown in FIG. 1, stepped portions B1 and B2 are present in the planar layout of control gates CG in the first embodiment. The stepped portion B1 arises due to projection of the contact pad portion CP of one control gate CG in a direction intersecting the extending direction of the gate wiring portion GW. The stepped portion B2 is formed by combination of outer edges of plural control gates CG.

The stepped portions B1 and B2 are different in shape from the rectilinear portion sandwiched in between adjacent control gates CG. Therefore, the shape of a gap formed in each of the stepped portions B1 and B2 can be a peculiar shape.

On the other hand, no portions corresponding to the stepped portions B1 and B2 in the first embodiment are existent in this third embodiment. Thus, it is possible to prevent the formation of a gap of a peculiar shape and the moisture resistance of the gaps in the semiconductor device can be made more uniform. As a result, the reliability of the semiconductor device is further improved.

### Fourth Embodiment

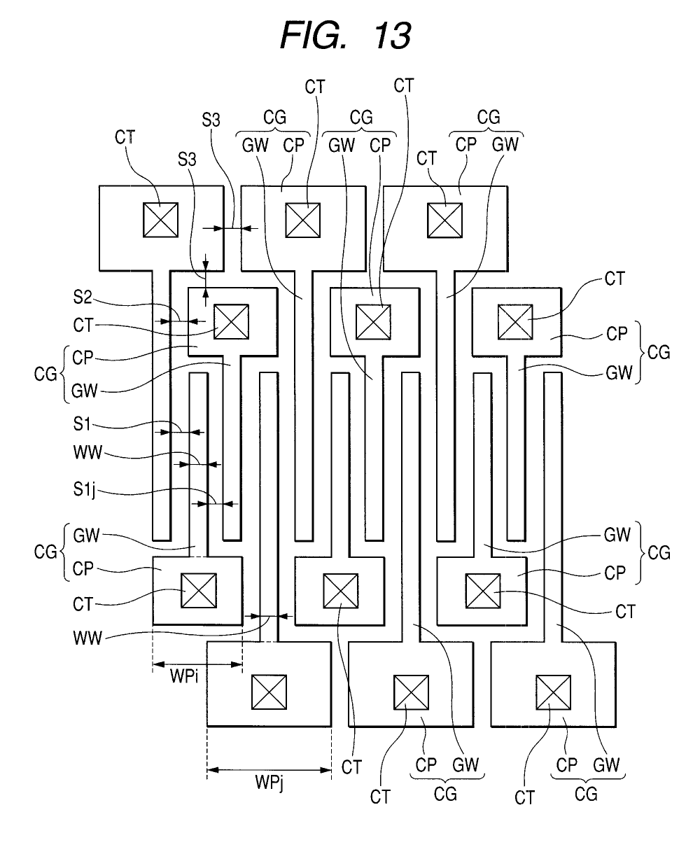

FIG. 13 is a schematic explanatory diagram showing a planar layout of gate electrodes (control gates) in a semiconductor device according to a fourth embodiment of the present invention.

Referring to FIG. 13, a contact pad portion CP is formed at one of both end portions in the length direction (vertical direction in the figure) of each gate wiring portion GW. In the layout of plural control gates CG such control pad portions CP are formed in an alternate manner. On respective one sides of the gate wiring portions a plurality of contact pad portions CP are arranged in two rows in the direction (lateral direction in the figure) intersecting the extending direction of the control gates CG.

Two types of contact pad portions CP are formed, one having a width dimension of WPi and the other having a width dimension of WPj which is larger than WPi. Of the contact pad portions CP thus arranged in two rows, those arranged in the row closer to the forming area (a middle stage in the figure) of the gate wiring portions GW have the width dimension WPi and those arranged in the farther row have the width dimension WPj.

Other constructional points of this fourth embodiment are almost the same as in the previous first or second embodiment. Therefore, the same elements as in the previous first or second embodiment are identified by the same reference numerals as in the previous embodiment and explanations thereof will here be omitted.

According to this fourth embodiment the closure shape of each gap can be made almost equal to that in the first or second embodiment, whereby the moisture resistance of the gap is improved and hence it is possible to prevent the deterioration in reliability of the semiconductor device.

Besides, unlike the first and second embodiments, on one side in the extending direction of the control gates CG, plural contact pad portions CP are arranged in two rows in the direction (lateral direction in the figure) intersecting the extending direction of the control gates CG. Therefore, in comparison with the one-row layout in the first and second embodiments, the width dimension of the contact part portion CP can be taken large, whereby an electric coupling with the control gate CG can be done in a more positive manner.

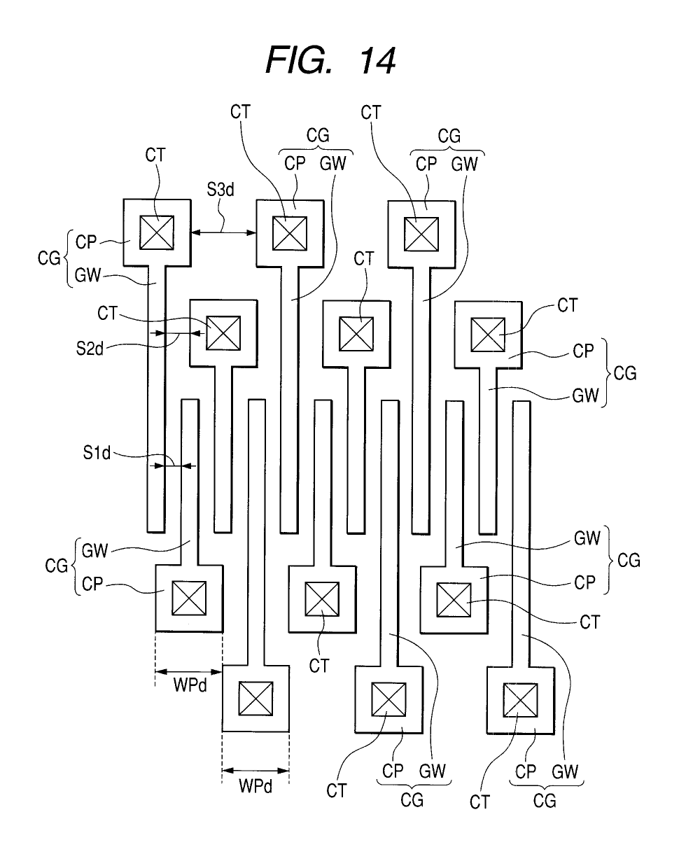

FIG. 14 shows a comparative example in comparison with this fourth embodiment. Contact pad portions CP are unified in width dimension to a single value (width dimension WPd) unlike this fourth embodiment. In this case, a spacing dimension S3d between contact pad portions CP positioned on an end side in the extending direction (vertical direction in the figure) of gate wiring portions GW is larger than a spacing dimension S1d between the gate wiring portions GW. As a result, a gap small in height dimension of a closed portion is formed between contact pad portions CP. This gap is low in moisture resistance, so that the reliability of the semiconductor device is deteriorated.

### Fifth Embodiment

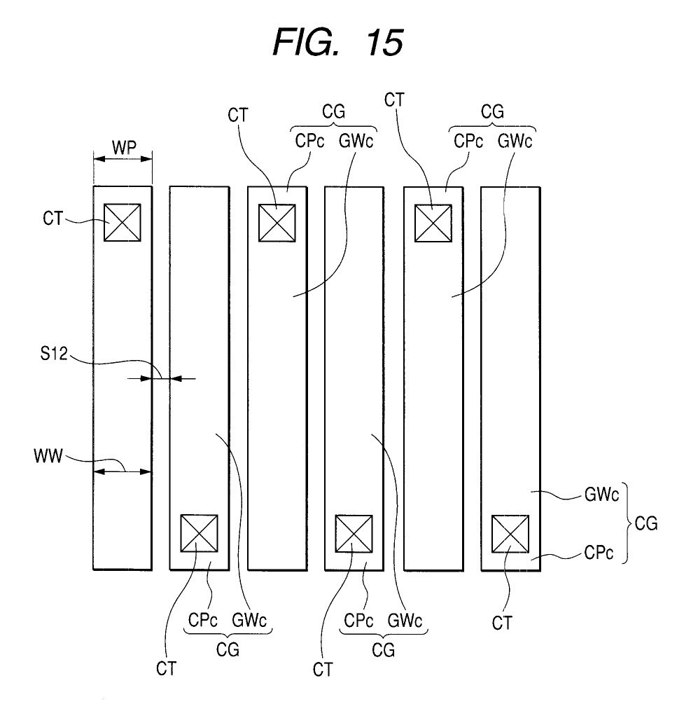

FIG. 15 is a schematic explanatory diagram showing a planar layout of gate electrode layers (control gates) in a semiconductor device according to a fifth embodiment of the present invention.

Referring to FIG. 15, in each control gate CG in this fifth embodiment, unlike the first and second embodiment, the width dimension of a contact pad portion CPc and that of a gate wiring portion GWc are both WP. As a result, the contact pad portion CPc and the gate wiring portion GWc are in a harmoniously united state. The distance between adjacent control gates CG is unified to a spacing dimension S12.

Other constructional points of this fifth embodiment are almost the same as in the previous first or second embodiment. Therefore, the same elements as in the previous first or second embodiment are identified by the same reference numerals as in the previous embodiment and explanations thereof will here be omitted.

According to this fifth embodiment, as in the second embodiment, gaps can be unified in closure shape to one and same shape and hence the moisture resistance thereof is improved, whereby it is possible to prevent the deterioration in reliability of the semiconductor device.

In this fifth embodiment, unlike the first embodiment, the pattern-to-pattern portion of the control gate CG is completely rectilinear. Consequently, gaps are formed more uniformly in comparison with the case where such pattern-to-pattern portion is complicated in shape. As a result, variations in moisture resistance of the gaps are suppressed and the reliability of the semiconductor device is improved.

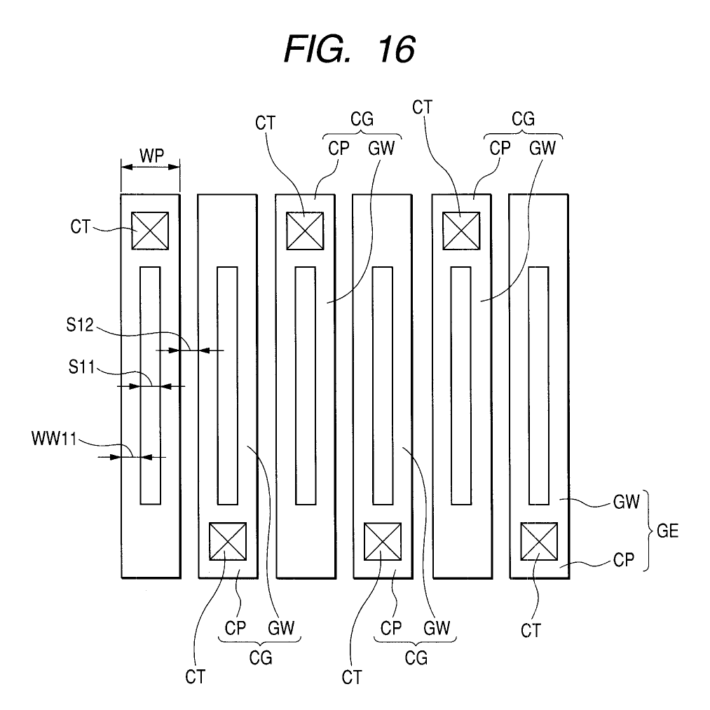

FIG. 16 shows a first modification of the fifth embodiment, in which each gate wiring portion GW is hollowed out in a rectangular shape of a width dimension S11. As a result, an intermediate portion in the extending direction of each control gate CG is a gate wiring portion GW of a width dimension WW11. The spacing dimension S11 is set equal to the spacing dimension S12.

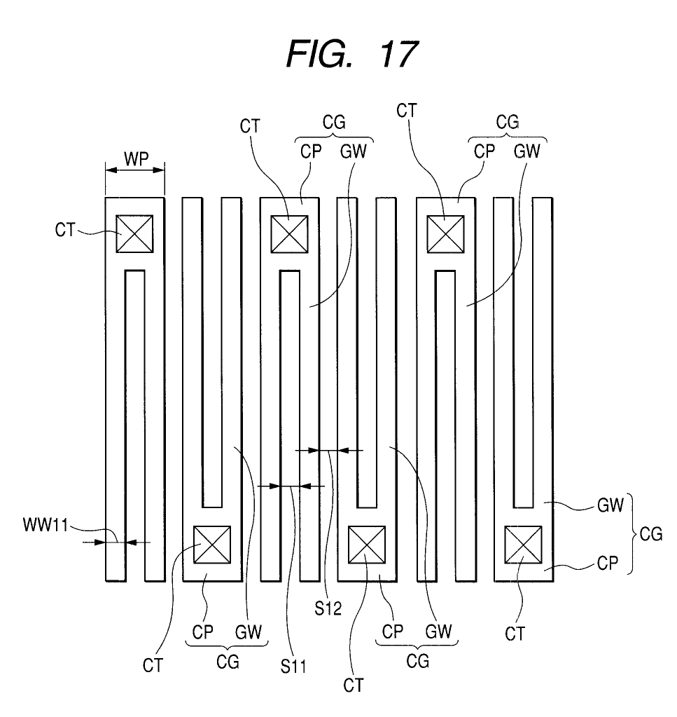

FIG. 17 illustrates a second modification of this fifth embodiment, in which a rectangular cutout portion of a width dimension is formed in each gate wiring portion GW. The spacing dimension S11 is set equal to the spacing dimension S12. As a result, the gate wiring portion GW comprises two wiring portions each having a width dimension of WW11.

### Sixth Embodiment

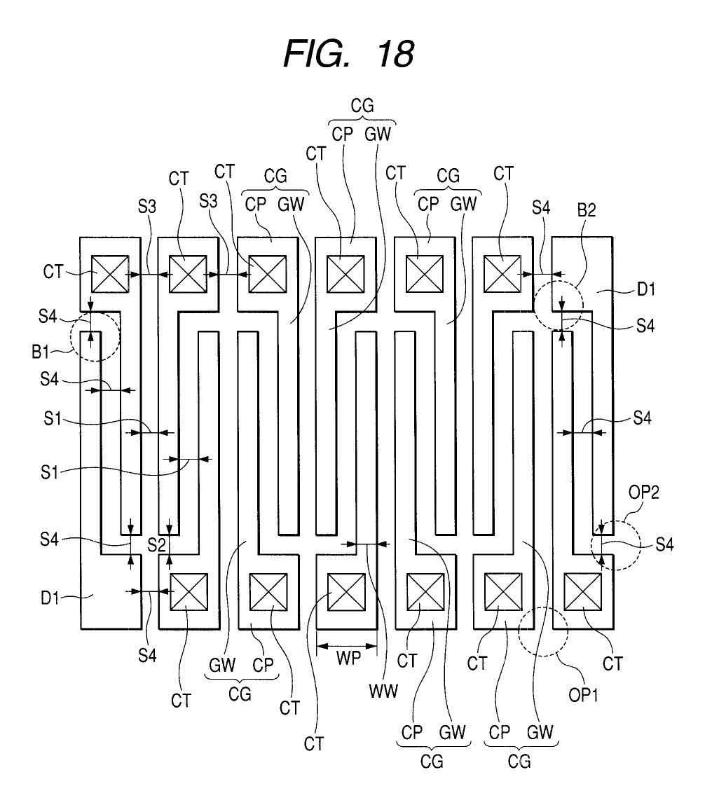

FIG. 18 is a schematic explanatory diagram showing a planar layout of gate electrode layers (control gates) and dummy conductive layers in a semiconductor device according to a sixth embodiment of the present invention.

Referring to FIG. 18, the semiconductor device of this sixth embodiment has the same construction of control gates CG as in the first embodiment, provided this sixth embodiment is different from the first and second embodiments in that dummy conductive layers D1 extending in the same direction as the extending direction of control gates CG are formed respectively at positions adjacent to gate wiring portions GW positioned at ends in the layout of the control gates CG.

The distance between each dummy conductive layer D1 and the gate wiring portion GW adjacent thereto corresponds to a spacing dimension S4. The spacing dimension S4 is set at 2.1 times or less as large as the spacing dimension S1 described in the first embodiment, preferably equal to S1. The distance between the dummy conductive layer D1 and the contact pad portion CP adjacent thereto is also set at the spacing dimension S4.

The potential of each dummy conductive layer D1 is set at a fixed potential or a floating potential while the semiconductor device is in operation. As the fixed potential there may be used, for example, the earth potential or supply potential. Since the potential of the dummy conductive layers D1 is thus the fixed potential or floating potential, the dummy conductive layers D1 do not have the function as control gates in the semiconductor device, but in the manufacturing process the dummy conductive layers D1 can be formed simultaneously with the control gates CG.

According to this sixth embodiment the stepped potions B1 and B2 in the first or second embodiment each correspond to a portion having a spacing dimension S4 (i.e., s1) between each dummy conductive layer D1 and the control gate CG adjacent thereto. As a result, also in each of the stepped portions B1 and B2 there is formed a gap of the same shape as that of the portion which is sandwiched in between control gates CG without any difference in height. Thus, gaps are formed more uniformly in the entire semiconductor device. Consequently, variations in moisture resistance of the gaps are diminished and the reliability of the semiconductor device is improved.

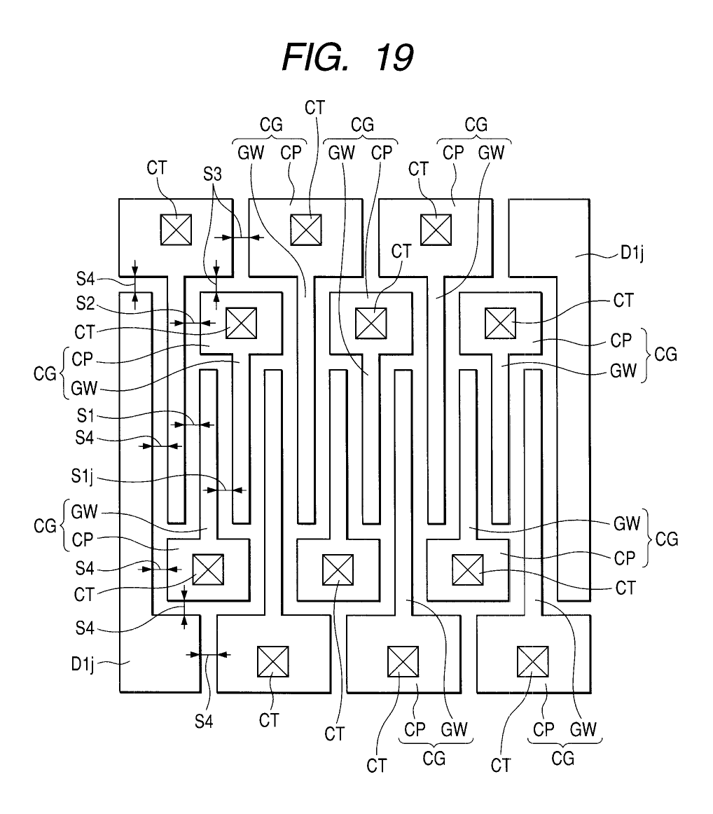

FIG. 19 is a schematic explanatory diagram showing a planar layout of control gates CG and dummy conductive layers D1j according to a modification of the sixth embodiment. In this modification, dummy conductive layers D1j for obtaining the same effect as that of the sixth embodiment described above are added to the semiconductor device of the fourth embodiment.

### Seventh Embodiment

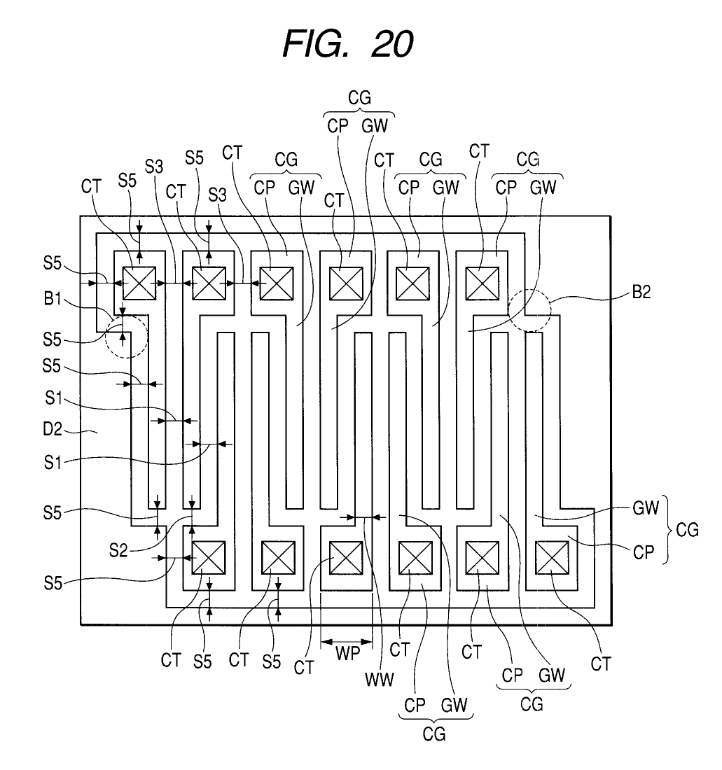

FIG. 20 is a schematic explanatory diagram showing a planar layout of gate electrode layers (control gates) and an outer periphery conductive layer in a semiconductor device according to a seventh embodiment of the present invention.

Referring to FIG. 20, the semiconductor device of his seventh embodiment has control gates CG of the same configuration as that in the first or second embodiment. A difference of this seventh embodiment from the first and second embodiments resides in that an outer periphery conductive layer D2 is formed so as to surround the whole of plural control gates CG.

The distance between the outer periphery conductive layer D2 and the control gates CG positioned inside the layer D2 is set at a spacing dimension S5. The spacing dimension S5 is set at 2.1 times or less as large as the spacing dimension S1 described in the first embodiment, preferably equal to S1. The distance between the outer periphery conductive layer D2 and the contact pad portion CP adjacent thereto is also set at the spacing dimension S5.

The potential of the outer periphery conductive layer D2 is set at a fixed potential or a floating potential during operation of the semiconductor device. As the fixed potential there may be used, for example, the earth potential or supply potential. Since the potential of the outer periphery conductive layer D2 is thus the fixed potential or floating potential, the outer periphery conductive layer D2 does not have the function as a control gate in the semiconductor device, but in the manufacturing process the outer periphery conductive layer D2 can be formed simultaneously with the control gates CG.

According to this seventh embodiment there is obtained the same effect as in the sixth embodiment in the point that the stepped portions B1 and B2 in the first and second embodiments are eliminated.

A description will now be given about the difference of this seventh embodiment from the sixth embodiment in point of effect. According to the planar layout of control gates CG in the sixth embodiment, open portions OP1 and OP2 are present. The open portion OP1 is a portion wherein the portion between adjacent control gates CG is continuous with an unpatterned wide area. The open portion OP2 is a portion wherein the portion between a control gate CG and a dummy conductive layer D1 is continuous with an unpatterned wide area.

Closed portions of gaps formed in the open portions OP1 and OP2 are exposed to liquid penetration not only from above but also sideways (from a wide unpatterned area) in the wet process during manufacture of the semiconductor device, thus sometimes resulting in the reliability of the semiconductor device being deteriorated.

On the other hand, in this seventh embodiment there are no portions corresponding to the open portions OP1 and OP2. Therefore, it is possible to suppress sideways penetration of liquid into the gaps and hence possible to further improve the reliability of the semiconductor device.

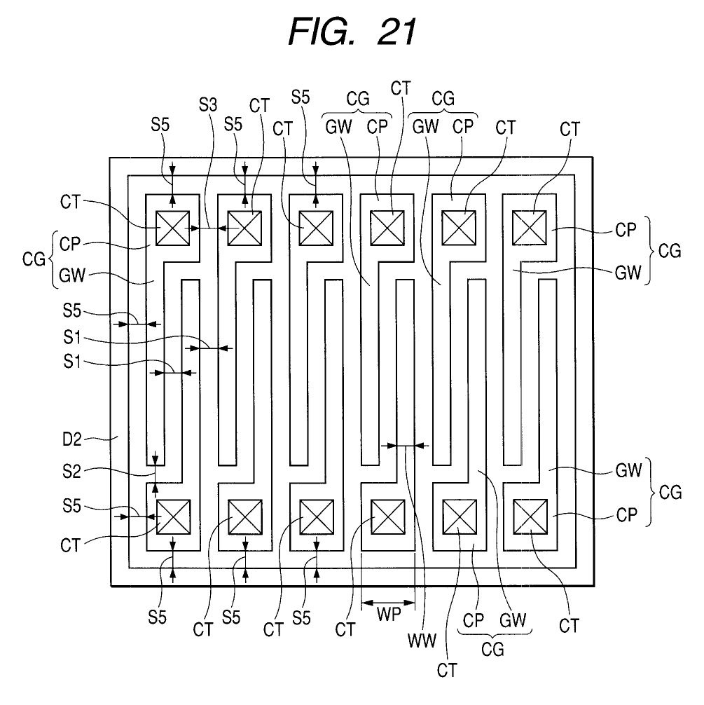

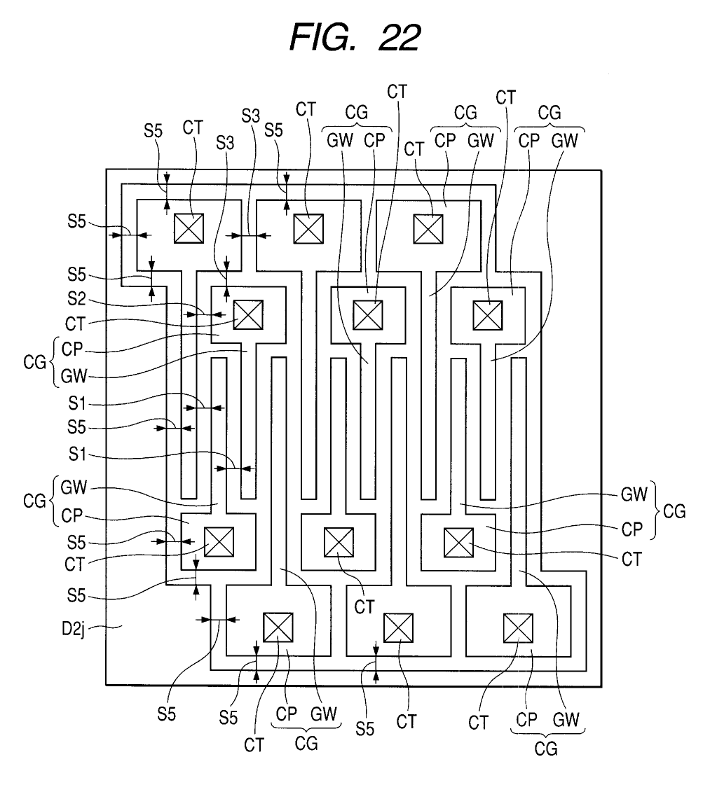

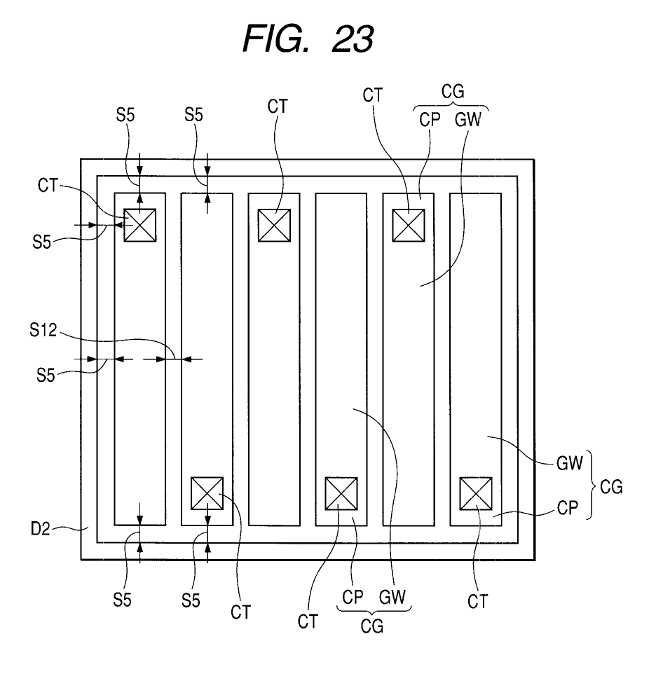

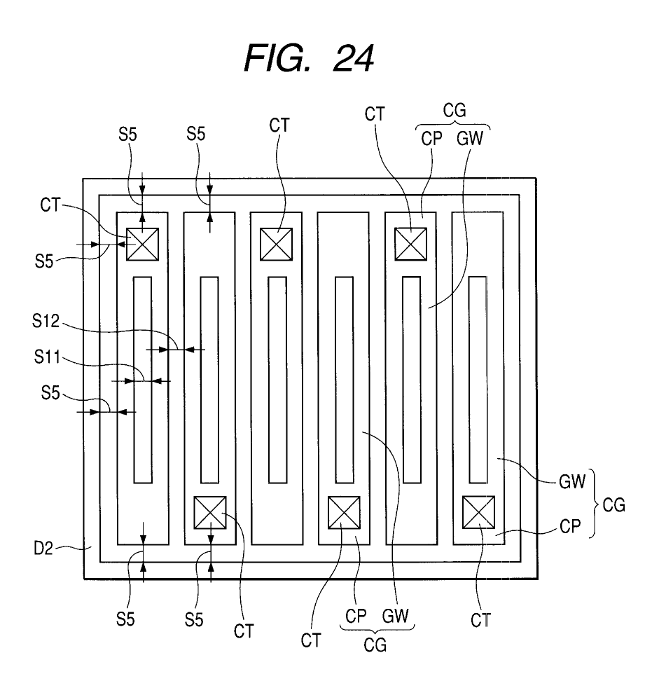

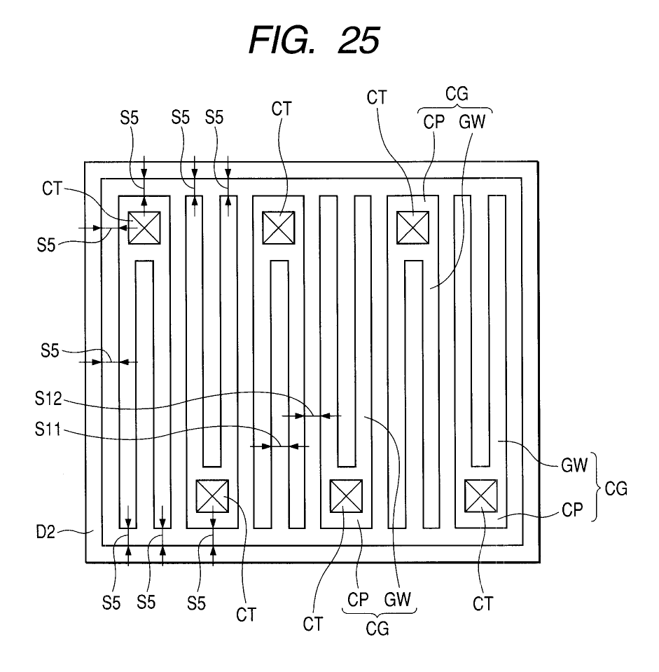

FIGS. 21 to 25 are schematic explanatory diagrams showing planar layouts of control gates CG and outer periphery conductive layers D2 in first to fifth modifications, respectively, of the seventh embodiment.

In the first and second modifications, an outer periphery conductive layer D2 is added to each of the semiconductor devices of the third and fourth embodiments in order to obtain the same effect as in the seventh embodiment just described above. In the third modification, an outer periphery conductive layer D2 is added, for the same purpose, to the semiconductor device of the fourth embodiment. Further, in the fourth and fifth embodiments, an outer periphery conductive layer D2 is added, for the same purpose, to each of the semiconductor devices of the first and second modifications of the fourth embodiment.

### Eighth Embodiment

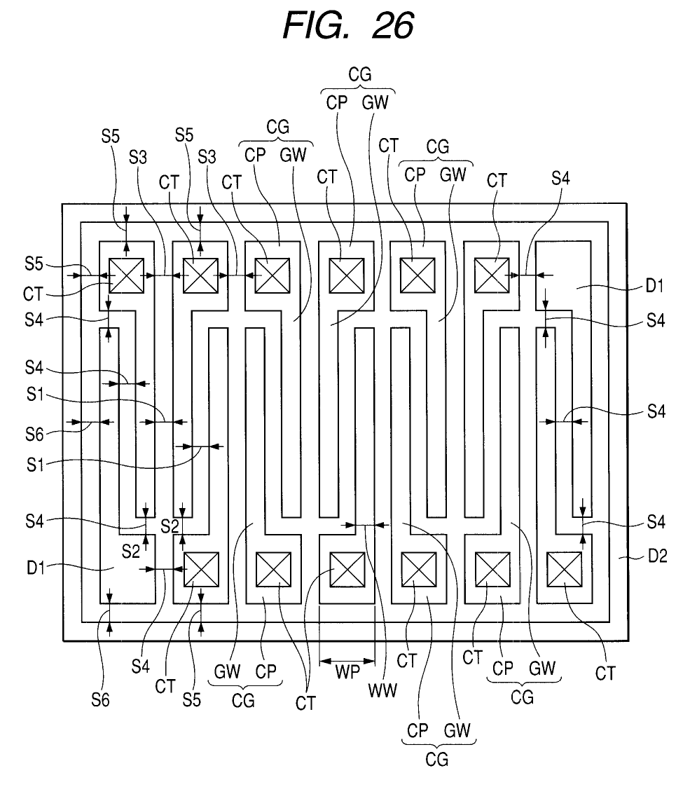

FIG. 26 is a schematic explanatory diagram showing a planar layout of gate electrode layers (control gates), dummy conductive layers and an outer periphery conductive layer in a semiconductor device according to an eighth embodiment of the present invention.

Referring to FIG. 26, the semiconductor device of this eighth embodiment has control gates CG and dummy conductive layers D1 of the same configurations as in the sixth embodiment. A difference of this eighth embodiment from the first and second embodiments resides in that an outer periphery conductive layer D2 is formed so as to surround the whole of the control gates CG and the dummy conductive layers D1.

A spacing dimension S6 which is the distance between each dummy conductive layer D1 and the outer periphery conductive layer D2 is set at 2.1 times or less as large as the foregoing spacing dimension S1, preferably equal to S1.

According to this eighth embodiment, like the seventh embodiment, it is possible to solve the problems caused by the stepped portions B1, B2 and the open portions OP1, OP2. In point of effect, this eighth embodiment is different from the seventh embodiment in that the dummy conductive layers D1 and the outer periphery conductive layer D2 as two types of conductive layers formed in the area surrounding the control gates CG can be placed in different potential conditions. As a result, it is possible to widen the degree of potential design freedom of the semiconductor device.

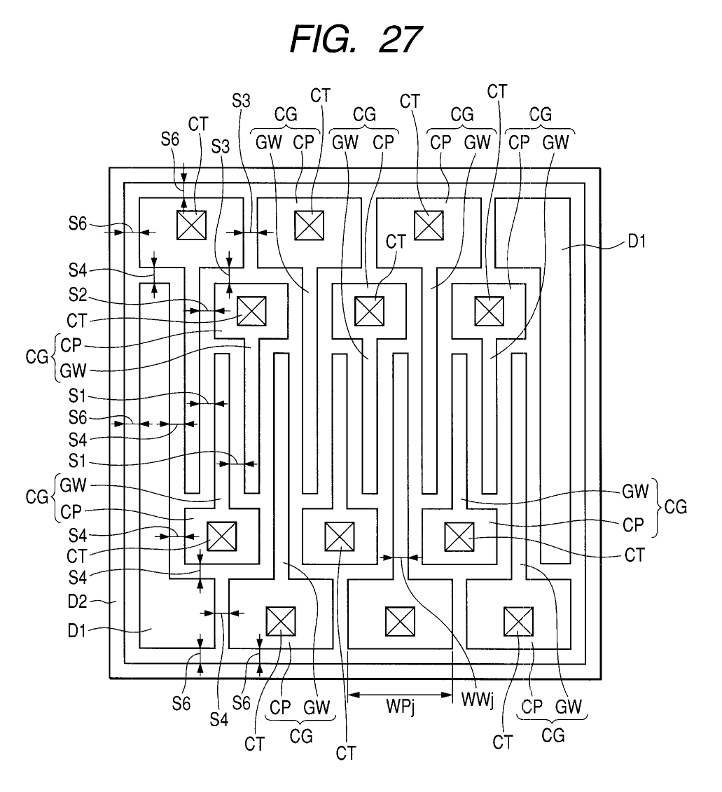

FIG. 27 is a schematic explanatory diagram showing a planar layout of control gates CG, dummy conductive layers D1 and an outer conductive layer D2 in a modification of the eighth embodiment. According to this modification, an outer periphery conductive layer D2 is added to the semiconductor device of the modification of the sixth embodiment in order to obtain the same effect as the effect of the eighth embodiment described above.

### Ninth Embodiment

In this ninth embodiment reference will be made to a NAND type flash memory as an example.

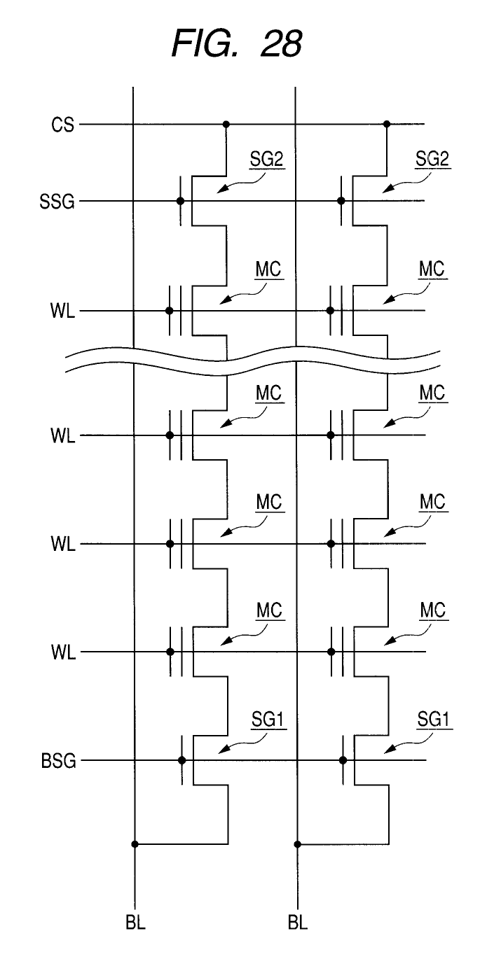

FIG. 28 is a diagram showing a schematic circuit configuration of a NAND type flash memory. Referring to FIG. 28, within a memory cell array of the NAND type flash memory there are arranged plural memory cells MC in a matrix shape. Control gates of memory cells MC arranged in a row direction (lateral direction in the figure) are coupled to word lines WL extending in the row direction.

Plural memory cells MC arranged in a column direction (vertical direction in the figure) are connected in series. Bit line-side selection transistors SG1 are connected to one end of the group of series-connected memory cells MC, while source-side selection transistors SG2 are connected to the other side of the memory cell group. The sources of the bit line-side selection transistors SG1 are connected to bit lines BL which are data lines, while the sources of the source-side selection transistors SG2 are connected to a common source line CS.

The gates of the bit line-side selection transistors SG1 arranged in the row direction are connected to a bit line-side selection gate line BSG extending in the row direction. The gates of the source line-side selection transistors SG2 arranged in the row direction are connected to a source line-side selection gate line SSG extending in the row direction.

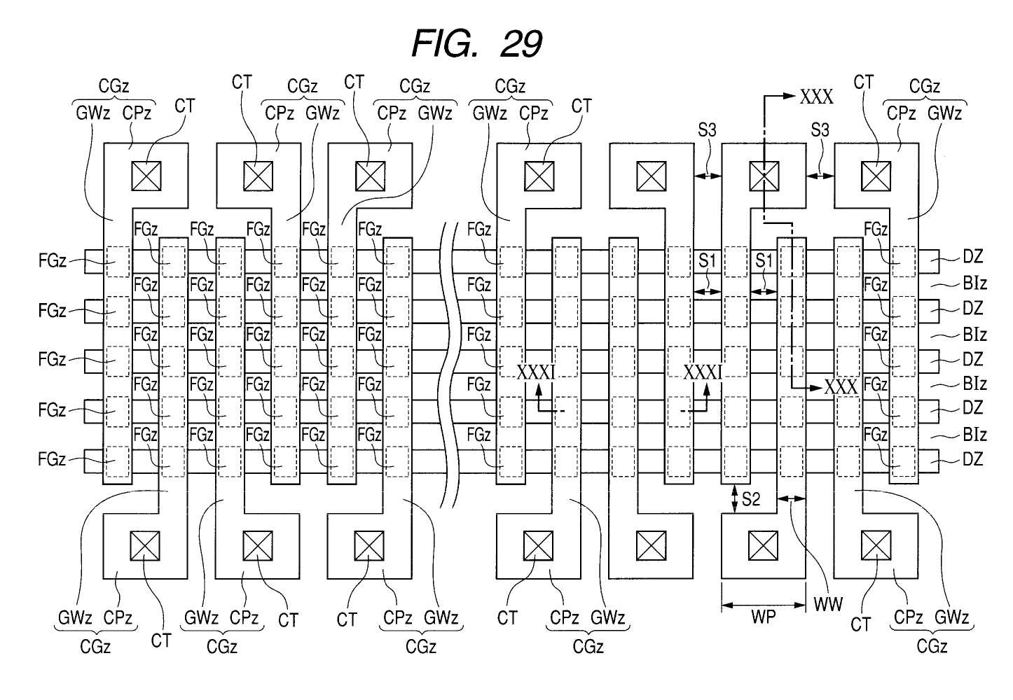

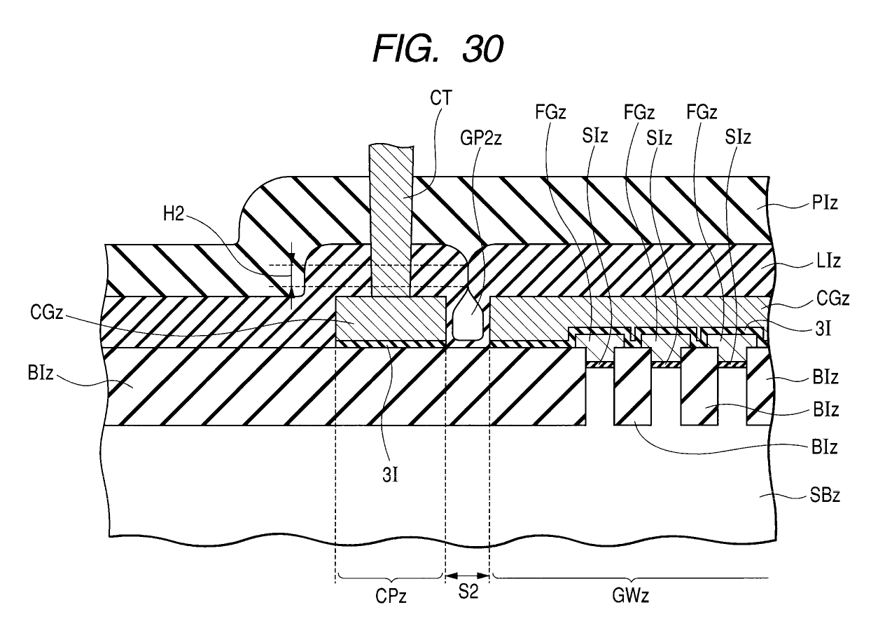

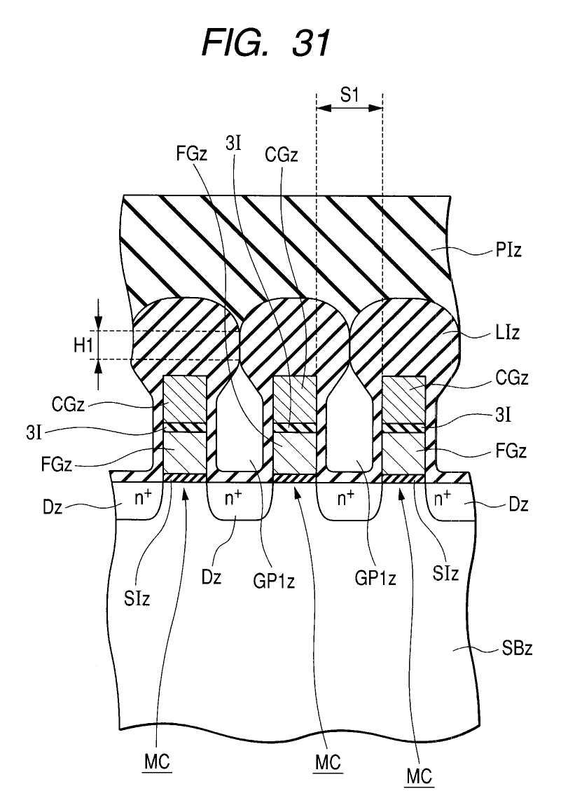

FIG. 29 is a plan view showing schematically the construction of a semiconductor device according to a ninth embodiment of the present invention. FIGS. 30 and 31 are schematic sectional views taken along lines XXX-XXX and XXXI-XXXI, respectively, in FIG. 29.

Referring mainly to FIG. 29, plural memory cells MC are arranged in a matrix shape on the surface of a p-type semiconductor substrate SBz formed of silicon for example. Word lines integral with control gates CGz of the memory cells MC extend in a row direction (vertical direction in the figure). Active regions with source/drain regions DZ of the memory cells MC formed therein extend in a column direction (lateral direction in the figure).

In a planar layout, each control gate CGz has a gate wiring portion GWz and a contact pad portion CPz. The gate wiring portion GWz is a principal portion of the control gate CGz and has a dimension WW in its width direction (lateral direction in the figure). The contact pad portion CPz is a portion positioned at one end of the control gate CGz and having a dimension WP larger than the dimension WW in its width direction (lateral direction in the figure).

Adjacent gate wiring portions GWz are spaced from each other by a distance of a spacing dimension S1 in a planar layout. Likewise, adjacent gate wiring portion GWz and contact pad portion CPz are spaced from each other by a distance of a spacing dimension S2. The control gates CGz are formed in such a manner that the spacing dimensions S1 and S2 are equal to each other.

Adjacent contact pad portions CPz are spaced from each other by a distance of a spacing dimension S3. The control gates CGz are formed in such a manner that the spacing dimension S3 is equal to the spacing dimensions S1 and S2.

Referring mainly to FIG. 30, a buried insulating film BIz is formed in the surface of the semiconductor substrate SBz to form STI (Shallow Trench Isolation). Active regions of the semiconductor substrate SBz are enclosed with the STI.

Referring mainly to FIG. 31, each of the plural memory cells MC has a pair of n-type source/drain regions Dz, a gate insulating film SIz, a floating gate FGz, a gate-to-gate insulating film 3I and a control gate CGz. The pair of source/drain regions DZ are formed spacedly from each other on the surface of an active region. The floating gate FGz is positioned through the gate insulating film SIz on the area sandwiched in between the pair of source/drain regions DZ.

The control gate CGz is formed on the floating gate FGz through the gate-to-gate insulating film 3I. The gate-to-gate insulating film 3I is, for example, an ONO (Oxide Nitride Oxide) film having a three-layer structure. An interlayer insulating film LIz and an insulating film PIz are formed on an upper surface of the control gate CGz.

Referring mainly to FIG. 30, a contact CT is formed through the interlayer insulating film LIz and the insulating film PIz. Through the contact CT the control gate CGz is connected electrically to wiring laid on top of the insulating film PIz. The buried insulating film BIz positioned below an end of the gate wiring portion GWz also extends downward beyond the terminal end of the gate wiring portion GWz and the contact pad portion CPz is formed thereon through the gate-to-gate insulating film 3I.

As noted above, the gate wiring portion GWz and the contact pad portion CPz are spaced from each other by a distance of a spacing dimension S2 equal to the spacing dimension S1. Consequently, a concave pattern is formed between the gate wiring portion GWz and the contact pad portion CPz. The interlayer insulating film LIz is formed so as to cover inner side faces, upper surfaces of side portions and bottom of the concave pattern. The interlayer insulating film LIz which covers inner side faces of the concave pattern projects inwards at an upper position of the concave pattern and the projecting portions are in contact with each other over the range of a height dimension H2 at a central upper position of the concave pattern. In this way a gap GP2z closed with the interlayer insulating film LIz is formed within the concave pattern.

That is, the gap GP2z is formed in the portion of the spacing dimension S1 located between the gate wiring portion GWz and the contact pad portion CPz. The gap GP2z has a closed portion over the range of the height dimension H2 at an upper position thereof.

The insulating film PIz is formed on the interlayer insulating film LIz. Referring mainly to FIG. 31, in the illustrated section, there are formed plural convex patterns each comprising the floating gate FGz and the control gate CGz stacked together. In a planar layout, the convex patterns correspond to the gate wiring portions GW and therefore the spacing between adjacent such convex patterns correspond the spacing dimension S1 between adjacent gate wiring portions GWz as noted above.

The interlayer insulating film LIz is formed so as to cover side faces and upper surfaces of the plural convex patterns and also cover the bottom between adjacent convex patterns. The interlayer insulating film LIz which covers side faces of the convex patterns project sideways at positions above the convex patterns and the projecting portions contact each other over the range of a height dimension H1 at the position between adjacent convex patterns. In this way gaps GP1z closed with the interlayer insulating film LIz are formed each between adjacent convex patterns.

That is, each gap GP1z is formed in the portion of the spacing dimension S1 between adjacent gate wiring portions GWz and it has a closed portion over the range of the height dimension H1 at an upper position thereof.

Both gaps GP1z and GP2z are formed in positions of pattern gaps of the control gates CGz, which pattern gaps are dimensionally equal in the gaps GP1z and GP2z because the spacing dimensions S1 and S2 are equal to each other. As a result, the gaps GP1z and GP2z are closed in similar shapes. Thus, the height dimension H1 of the closed portion of each gap GP1z and the height dimension H2 of the closed portion each gap GP2z are equal to each other.

According to this ninth embodiment, the spacing dimension S2 (FIG. 30) between the gate wiring portion GWz and the contact pad portion CPz and the spacing dimension S1 (FIG. 31) between adjacent gate wiring portions GWz are equal to each other. Consequently, the interlayer insulating film LIz formed between the gate wiring portion GWz and the contact pad portion CPz and the interlayer insulating film LIz formed between adjacent gate wiring portion GWz close in the same manner. Thus, the height dimension H2 of the cloed portion of each gap GP2z (FIG. 30) and the height dimension H1 of the closed portion of each gap GP1z (FIG. 31) become equal to each other.

Since the height dimension H2 of the closed portion of each gap GP2z and the height dimension H1 of the closed portion of each gap GP1z are thus equal to each other, the gap GP2z can prevent the penetration of liquid into the interior thereof to about the same degree as the gap GP1z formed between adjacent gate wiring portions GWz. That is, the gap GP2z can have about the same degree of moisture resistance as the gap GP1z. As a result, it is possible to prevent liquid form penetrating only the gap GP2z in the wet process and causing the corrosion of wiring, thus making it possible to prevent the deterioration in reliability of the semiconductor device.

The control gates CGz are each formed in such a manner that the spacing dimension S3 (FIG. 29) between adjacent contact pad portions CPz is equal to the spacing dimensions S1 and S2 referred to above. Consequently, the height dimension of the closure portion of the gap formed between adjacent control gates CGz also becomes equal to the height dimensions H1 and H2. As a result, it is possible to prevent liquid from penetrating only the gap between adjacent contact pad portions CPz in the wet process and causing the corrosion of wiring, thus permitting prevention of a lowering in reliability of the semiconductor device.

It should be understood that the above embodiments are illustrative and not limitative in every respect. The scope of the present invention is shown not by the above description but by the scope of claims and it is contemplated that meanings equal to the scope of claims and all changes falling under the scope of claims are included in the scope of the present invention.

The present invention is applicable particularly advantageously to semiconductor devices having gaps each between adjacent wiring lines and manufacturing methods for such semiconductor devices.

1. A semiconductor device comprising:
a semiconductor substrate having a main surface;
a plurality of gate electrode layers formed over the semiconductor substrate so as to extend in one and same direction in a planar layout, the gate electrode layers each having a gate wiring portion and a contact pad portion; and
an interlayer insulating film formed over the gate electrode layers and gaps so as to leave the gaps each between adjacent said gate wiring portions and also between adjacent said gate wiring portion and said contact pad portion,
wherein a second spacing which is the distance between adjacent said gate wiring portion and said contact pad portion is 2.1 times or less as large as a first spacing which is the distance between adjacent said gate wiring portions.

2. A semiconductor device according to claim 1, wherein the second spacing is equal to the first spacing.

3. A semiconductor device according to claim 1, wherein a third spacing which is the distance between adjacent said contact pad portions is 2.1 times or less as large as the first spacing.

4. A semiconductor device according to claim 3, wherein the third spacing is equal to the first spacing.

5. A semiconductor device according to claim 1, wherein the width of the contact pad portion is larger than the width of the gate wiring portion.

6. A semiconductor device according to claim 1, wherein the width of the contact pad portion is equal to the width of the gate wiring portion.

7. A semiconductor device according to claim 1, wherein the gate electrode layers further include a dummy conductive layer, the dummy conductive layer being disposed in a direction intersecting the extending direction of the gate electrode layers and extending in the same direction as the extending direction of the gate electrode layers at a position adjacent to an end of the layout of the gate electrode layers, and the distance between the gate electrode layer positioned at the end of the layout and the dummy conductive layer is 2.1 times or less as large as the first spacing.

8. A semiconductor device according to claim 7, wherein the distance between the gate electrode layer positioned at the end of the layout and the dummy conductive layer is equal to the first spacing.

9. A semiconductor device according to claim 7, wherein the potential of the dummy conductive layer is fixed.

10. A semiconductor device according to claim 7, wherein the dummy conductive layer does not have a function as a control gate.

11. A semiconductor device according to claim 1, further comprising an outer periphery conductive layer which surrounds the gate electrode layers.

12. A semiconductor device according to claim 11, wherein the distance between each of the gate electrode layers and the outer periphery conductive layer is 2.1 times or less as large as the first spacing.

13. A semiconductor device according to claim 12, wherein the distance between each of the gate electrode layers and the outer periphery conductive layer is equal to the first spacing.

14. A semiconductor device according to claim 11, wherein the potential of the outer periphery conductive layer is fixed.

15. A semiconductor device according to claim 11, wherein the outer periphery conductive layer does not have a function as a control gate.

16. A semiconductor device according to claim 1, wherein the gate electrode layers are control gate electrode layers, and between each of the control gate electrode layers and the semiconductor substrate there is formed a floating gate electrode layer insulated from the control gate electrode layer.
